(19) United States
(12) Patent Application Publication
(10) Pub. No.: US 2004/0021230 A1
(43) Pub. Date: Feb. 5, 2004

(54) Ultra thin stacking packaging device

(75) Inventors: Chen-Jung Tsai, Hsin-Chu (TW); Jui-Chung Lee, Yun-Lin (TW); Chih-Wen Lin, Hsin-Chu (TW)

Correspondence Address: LOW HAUPTMAN GILMAN & BERNER, LLP, Suite 310, 1700 Diagonal Road, Alexandria, VA, 22314, US

(73) Assignee: Macronix International Co., Ltd.

(21) Appl. No.: 10/211,278

(22) Filed: Aug. 5, 2002

(51) Int. Cl. H01L 23/48

(52) U.S. Cl. 257/777

(57) ABSTRACT

A stacking multi-chip device comprises a substrate having a recess, stud bumpers or conductive stud strips thereon. A low die has a back surface affixed in the recess or the substrate, and has a first active surface comprising a plurality of bonding pads. The bonding pads of the low die have a set of elongate conductors connected to the substrate. An upper die has a back surface and a second active surface comprising a plurality of bonding pads. The bonding pads of the upper die have a plurality of stud bumpers connected to the stud bumpers, conductive stud strips, or the substrate by the method of reflow or anti-tropic conductive film. The second active surface is faced towards said first active surface and is offset stacked atop the low die to expose all bonding pads.

### BACKGROUND OF THE INVENTION

1. Field of the Invention

The invention relates to a stacking semiconductor packaging device, and more particularly relates to stacking multi-chip packaging device.

2. Description of the Prior Art

In order to interface a die with other circuitry, normally it is mounted on a lead-frame paddle or a multichip module substrate.

In many cases, multichip devices can be fabricated faster and more cheaply than a corresponding single IC which incorporates the same or different functions. Current multichip module construction typically consists of a printed circuit board substrate to which a series of separate components are directly attached. This technology is advantageous because of the increase in circuit density achieved. With increased density comes improvements in signal propagation speed and overall device weight. While integrated circuit density increases at a significant rate, the interconnection density has become a significant limiting factor in the quest for miniaturization.

U.S. Pat. No. 5,721,452 discloses an offset die stacking arrangement with one upper level die having a width which is less than the distance separating the opposing bonding sites of the underlying die. The upper die is suspended above the lower die on one or more pillars and rotated within a plane parallel to the lower die through an angle. Once the dice are fixed in this manner, the entire assembly is subjected to the wire bonding process with all of the bonds being made in the same step.

Furthermore, U.S. Pat. No. 5,998,864 discloses another one offset die stacking arrangement with all of active-face-down dies connected to substrate via conductors. U.S. Pat. No. 5,886,412 discloses stacking dies and a substrate with a recess to be placed the lower die. All of stacking dies are faced up with their active surfaces, and the whole height is reduced by the method.

### SUMMARY OF THE INVENTION

It is one object of the present invention to provide an ultra thin stacking package. The stacking package is offset stacked with active-face-to-active-face dies, and is implemented by the interconnection technology of wire bonding or bumping, which has reduced whole height.

It is another object of the present invention to provide a stacking semiconductor packaging device. The stacking semiconductor packaging device has the minimum overall height of the assembly, and has facilitating ease and efficiency of wire bonding by the recess or the bumping of a substrate.

In the present invention, a stacking multi-chip device comprises a substrate having a recess, stud bumpers or conductive stud strips thereon. A low die has a back surface affixed in the recess or the substrate, and has a first active surface comprising a plurality of bonding pads. The bonding pads of the low die have a set of elongate conductors connected to the substrate. An upper die has a back surface and a second active surface comprising a plurality of bonding pads. The bonding pads of the upper die have a plurality of stud bumpers connected to the stud bumpers, conductive stud strips, or the substrate by the method of reflow or anti-tropic conductive film. The second active surface is faced towards said first active surface and is offset stacked atop the low die to expose all bonding pads.

### BRIEF DESCRIPTION OF THE DRAWINGS

A better understanding of the invention may be derived by reading the following detailed description with reference to the accompanying drawings wherein:

FIGS. 1A-1E are plane schematic diagrams illustrating the various stacking arrangements of a lower die and an upper die in accordance with the present invention;

FIGS. 2A-2C are cross-sectional schematic diagrams illustrating the connection methods of a lower die and an upper die with a substrate in accordance with the present invention;

FIGS. 3A-3E are cross-sectional schematic diagrams illustrating the connection methods of an upper die and a lower die with a substrate in accordance with the present invention;

FIGS. 4A-4C are cross-sectional schematic diagrams illustrating various stacking semiconductor packaging devices in accordance with the present invention; and

FIG. 5 is a schematically cross-sectional diagram illustrating another interconnection between the upper die and the substrate in accordance with the present invention.

### DESCRIPTION OF THE PREFERRED EMBODIMENT

While the invention is described in terms of a single preferred embodiment, those skilled in the art will recognize that many devices described below can be altered as well as other substitutions with same function and can be freely made without departing from the spirit and scope of the invention.

Furthermore, there is shown a representative portion of video signals of the present invention in enlarged. The drawings are not necessarily to scale for clarify of illustration and should not be interpreted in a limiting sense. Furthermore, the present invention can be applied on various multi-chip devices or packages.

In the present invention, a stacking multi-chip device comprises a substrate having a recess, stud bumpers or conductive stud strips thereon. A low die has a back surface affixed in the recess or the substrate, and has a first active surface comprising a plurality of bonding pads. The bonding pads of the low die have a set of elongate conductors connected to the substrate. An upper die has a back surface and a second active surface comprising a plurality of bonding pads. The bonding pads of the upper die have a plurality of stud bumpers connected to the stud bumpers, conductive stud strips, or the substrate by the method of reflow or anti-tropic conductive film. The second active surface is faced towards said first active surface and is offset stacked atop the low die to expose all bonding pads.

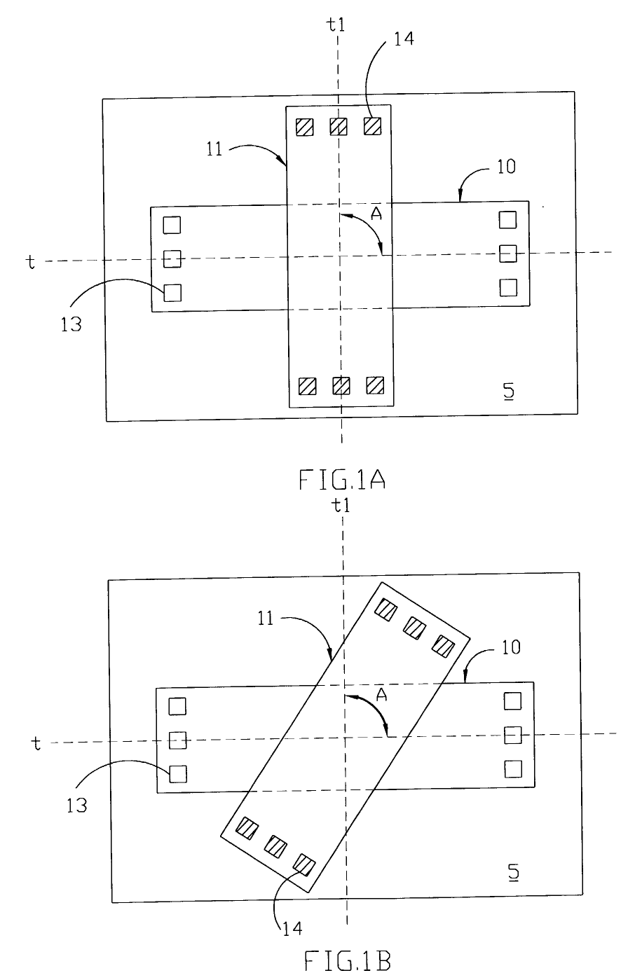

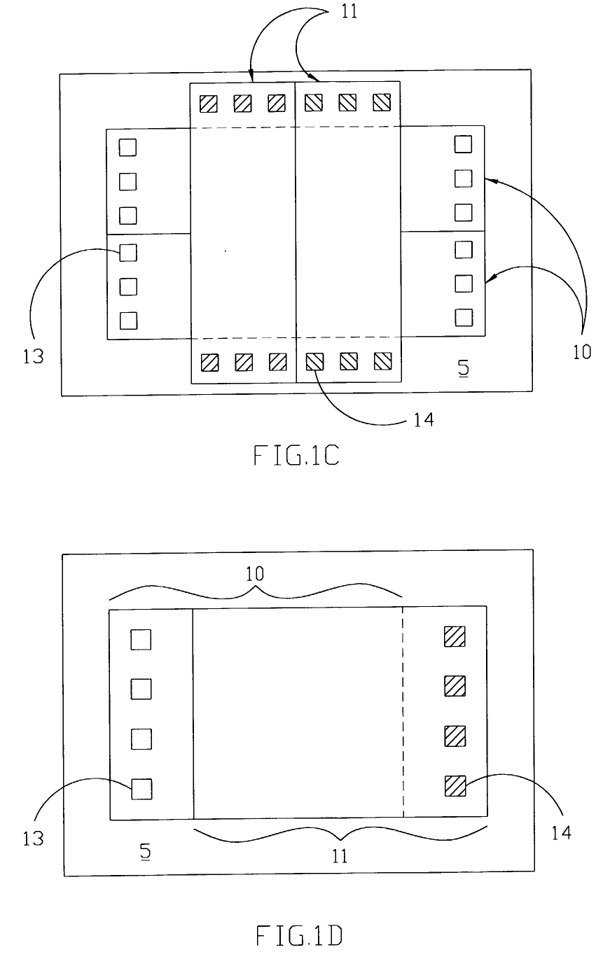

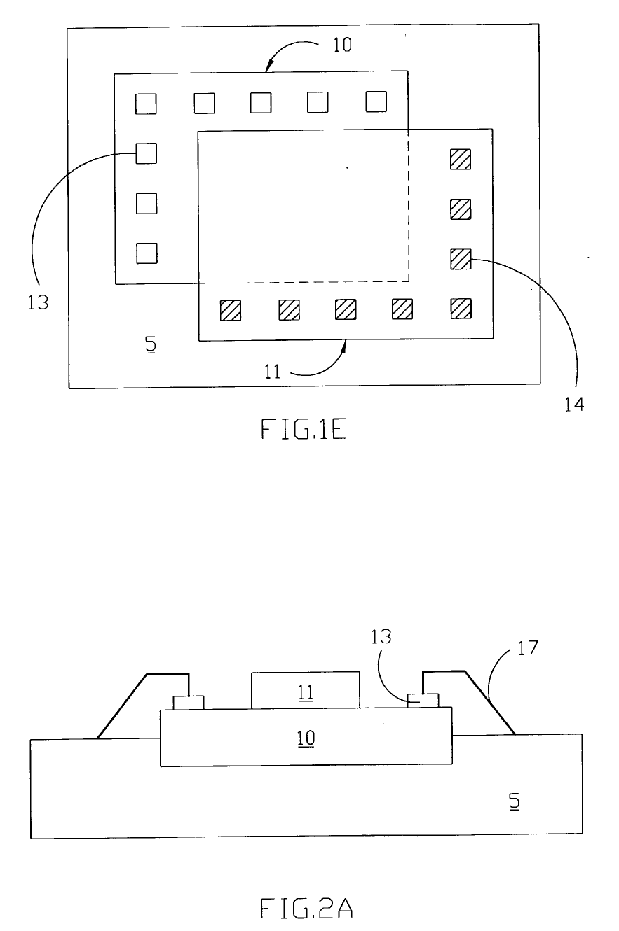

The multichip device of the first embodiment is comprised of a substrate 5 which includes one or more Z-direction multichip stacks. For the purposes of this explanation, depicted in FIG. 1, the substrate 5 lies generally in the XY plain and the chip stacks extend upwardly parallel with the Z axis. However, it should be noted that the invention is not limited to this orientation and the coordinate system could describe stacks extending in the X or Y directions, as well as any other direction. Consequently, directional and position descriptors such as upper, lower, above, below, etc. are adopted merely for the convenience of illustration and explanation and are not intended to limit the orientation or scope of the invention.

Referring first in FIG. 1A, a lower first die 10 has a back surface faced downward to the substrate 5 and a bonding surface (active surface) upward. The substrate 5 may be a ceramics substrate, a substrate with organic material, or a substrate with the mixture material thereof. The back surface of the lower first die 10 can be affixed to the substrate 5 with a liquid non-conductive material or a solid film. Furthermore, the bonding surface includes a plurality of bonding pads 13 generally lay adjacent opposing side edges. An upper second die 11 also has a back surface faced upward and a bonding surface downward to the lower first die 10. Thus, a plurality of bonding pads 14 of the upper second die 11 are downward faced to the substrate 5 and generally lay adjacent opposing side edges. The width of the upper second die 11 must be less than or equal to the length “L” of the lower first die 10.

Furthermore, the upper second die 11 is cross and angularly offset with respect to the lower first die 10 at an angle “A” sufficient to insure that the upward bonding pads 13 and downward bonding pads 14 are not interfered with each another. The angle of offset “A” represents the angle between the longitudinal centerline “t” of the lower first die 10 and the longitudinal centerline “t1” of the upper second die 11. The angular rotation of the upper second die 11 occurs in a plane which is generally parallel to the upward bonding surface 15 of the lower first die 10. Thus, for the lower first die 10, two edge portions included the upward bonding pads 13 are exposed and separated each other by the upper second die 11. For upper second die 11, as well as the lower first die 10, includes two edge portions having the downward bonding pads 14 exposed and separated each other.

As shown in FIG. 1B, the upper second die 11 is rotated with an angular offset for any specific design or requirement. Of course, the upward bonding pads 13 of the lower first die 10 and the downward bonding pads 14 of the upper second die 11 are insured not to interfere with each another.

As shown in FIG. 1C, there are multitudes of lower first dies 10 arranged adjacent to each other on the substrate 5 and multitudes of upper second dies 11 arranged adjacent to each other on those lower first dies 10. The width summation of the upper second dies 11 is less than the length of any one of the lower first dies such that the bonding pads of the lower first dies aren't interfered with ones of the upper second dies 11. Similar to the first embodiment of the present invention, all lower first dies 10 have back surfaces faced downward to the substrate 5 and bonding surfaces upward. All upper second dies 11 have back surfaces upward and bonding surfaces faced downward to those lower first dies 10. In the embodiment, these lower first dies 10 and upper seconds dies 11 have dimensions and geometries as same as ones of the first embodiment.

For interconnection between a plurality of dies, there are two methods applied. If there is no signal transmission between two dies on the different stack levels, an affixing material for the above-mentioned stacking is employed for connecting the upper and lower dies. On the other hand, if there is signal transmission between the two dies on the different stack levels, redistribution or flip chip technology combined with SMT technology is applied on the interconnection between the two dies. The die arrangements of the present invention are not limited on the dies with same dimensions or geometries as long as the bonding pads of any die aren't interfered with those of the other dies.

Depicted in FIG. 1D is the other embodiment of the present invention, wherein the upper second die 11 is offset in one direction from the lower first die 10 on the substrate 5. The geometry and dimension of the upper second die 11 are similar to those of the lower first die 10. The upper second die 11 is shifted offset so that the edge portion of the lower first die 10 is exposed. The exposed edge portion of the lower first die 10 comprises the upward bonding pads 13 and is rectangular. The upper second die 11 with a same dimension as the lower first die 10, also be exposed the rectangular edge portion comprising the downward bonding pads 14.

When the dimension of the upper second die 11 is larger than the dimension of the lower first die (not shown in a figure), such that the exposed edge portion of the upper second die is U-shaped and the exposed edge portion of the lower first die is rectangular. The upward bonding pads are distributed on the rectangular exposed edge portion of the lower first die and the downward bonding pads are on the U-shaped exposed edge portion of the upper second die.

FIG. 1E is the another embodiment in which the upper second die 11 is shifted offset in two directions from the lower first die 10. The lower first die 10 is exposed a L-shaped edge portion on which the bonding pads 13 are distributed. The upper second die 11 is also exposed another L-shaped edge portion on which the bonding pads 14 are distributed.

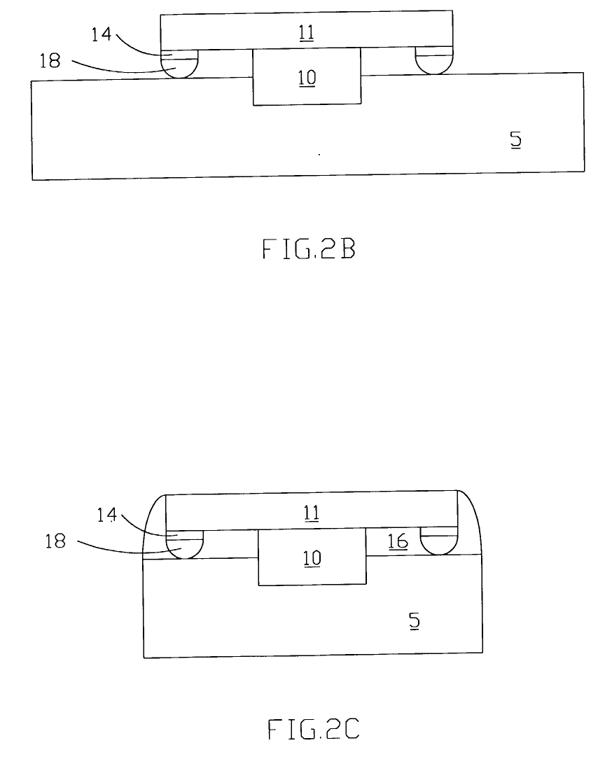

FIG. 2A is a cross-sectional schematic diagram illustrating the interconnection of the lower first die of FIG. 1A in accordance with the present invention. It is noted that the interconnections of the upper die aren't shown therein for simplicity. Depicted in FIG. 2A, the lower first die 10 is affixed in the recess of the substrate 5. The depth of the recess is dependent for requirement of design. In the FIG. 2A, the depth of the recess is less than the height of the lower first die 10, but it is not limited therein. The recess of the substrate of the present invention, not only reduces the whole height of a package device, but also enables the interconnection manufacture of the upper second die and the substrate to go through easily.

The back surface of the lower first die 10 is affixed to the recess of the substrate 5 with liquid non-conductive gel or solid film. In the present invention, multitudes of metal wires 17 are connected between the bonding pads 13 and the substrate 5 by the method of wire bonding attachment. For reducing the whole packing height, the arc height of metal wires 17 would be controlled within the height of the upper second die 11. Furthermore, the interconnection method for the lower first die 10 can be replaced by other interconnection methods, such as the interconnection method of tape automatic bonding (TAB) or tape carrier packaging (TCP), or the interconnection method of lead-frame attachment.

FIG. 2B is a schematically cross-sectional view illustrating the interconnection of the upper die in accordance with the first embodiment in FIG. 2A. It is also note that the interconnection methods are also applied on other embodiments of the present invention, such as ones mentioned in FIGS. 1B-1E. On the other hand, the interconnections of the lower die in the recess of the substrate 5 aren't shown therein for simplicity. In the present invention, the active surface of the upper second die 11 is affixed to the active surface of the lower first die 10 with non-conductive liquid or solid film. Furthermore, the downward bonding pads 14 of the upper second die 11 are connected to the substrate 5 by multitudes of predetermined stud bumpers 18. The predetermined stud bumpers 18, such as gold bumpers or solder bumpers, are implemented by the technology of wire bonding or flip-chip bumping. To be specific, the face-to-face arrangement for the lower first die 10 and the upper second die 11 has advantages on the whole stacking height. For example, there is no arc height issue on the bonding types of the upper second die 11. In addition to no arc height, the lower first die 10 is in the recess of the substrate 5 so that the whole stacking height is reduced greatly.

FIG. 2C is a schematically cross-sectional diagram illustrating the upper die and the substrate of FIG. 2A in accordance with the present invention. In this embodiment, for reinforcement of reliability between the upper second die 11 and the substrate 5, liquid non-conductive gel 16 is under-filled between the upper second die 11 and the substrate 5, and further wraps the bonding pads 14 and stud bumpers 18 therein.

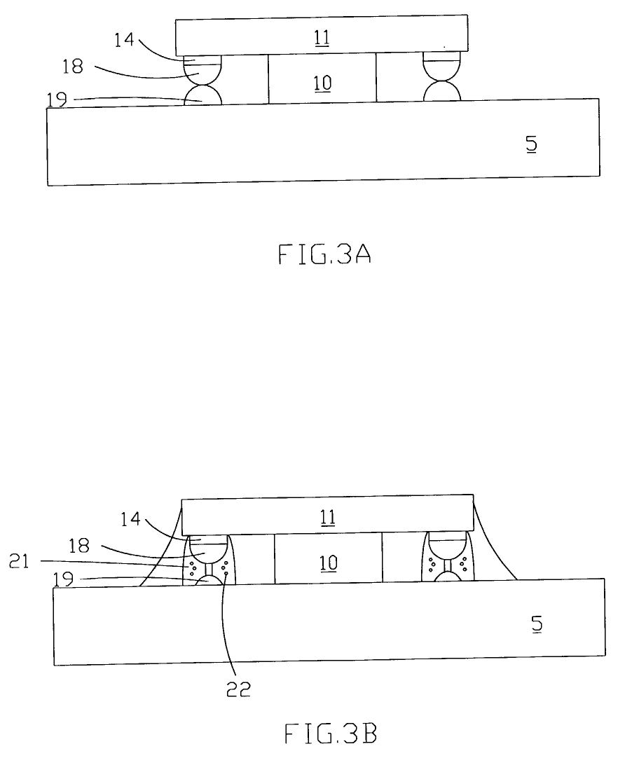

FIG. 3A is a schematically cross-sectional diagram illustrating the other interconnection of the upper die and the substrate in accordance with the present invention. In the embodiment, the active surface of the upper second die 11 is affixed to the active surface of the lower first die 10 by the liquid non-conductive gel or solid conductive film. The bonding pads 14 of the upper second die 11 are formed with predetermined stud bumpers 18, such as gold bumpers, or solder bumpers, by the technology of wire bonding or flip-chip bumping. On condition of no recess of the substrate and for flexible manufacture, there are predetermined stud bumpers 19 on the substrate 5 corresponding to the locations of the stud bumpers 18. The predetermined stud bumpers 19, such as gold bumpers, solder balls, or solder bumpers, are formed by the technology of wire bonding or flip-chip bumping. Next, the stud bumpers 18 are directly connected with the stud bumpers 19 by reflow method. Alternatively, the stud bumpers 18 are also connected with the stud bumpers 19 with anti-tropic conductive film. Furthermore, shown in FIG. 3B, liquid non-conductive gel 21 is filled around the stud bumpers 18 and the stud bumpers 19 for reinforcement of reliability between the upper second die 11 and the substrate 5.

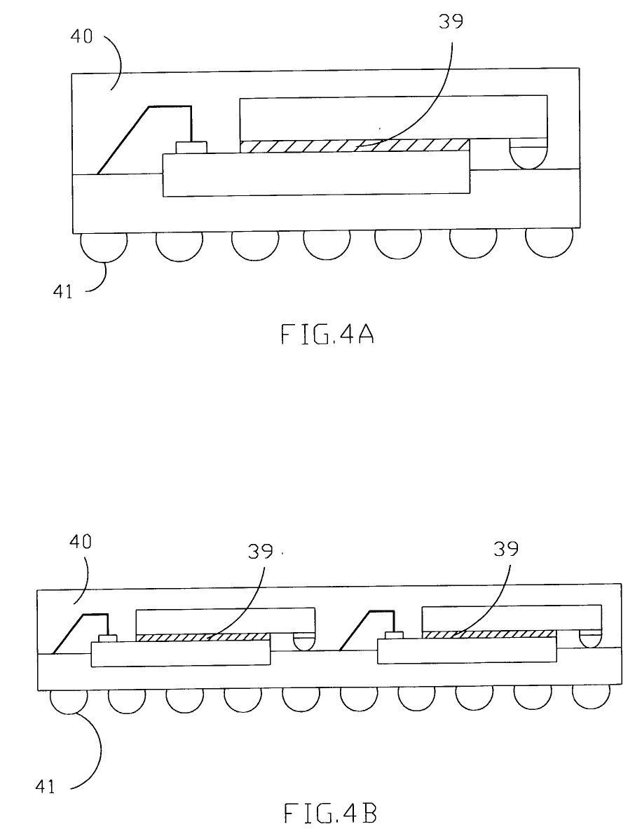

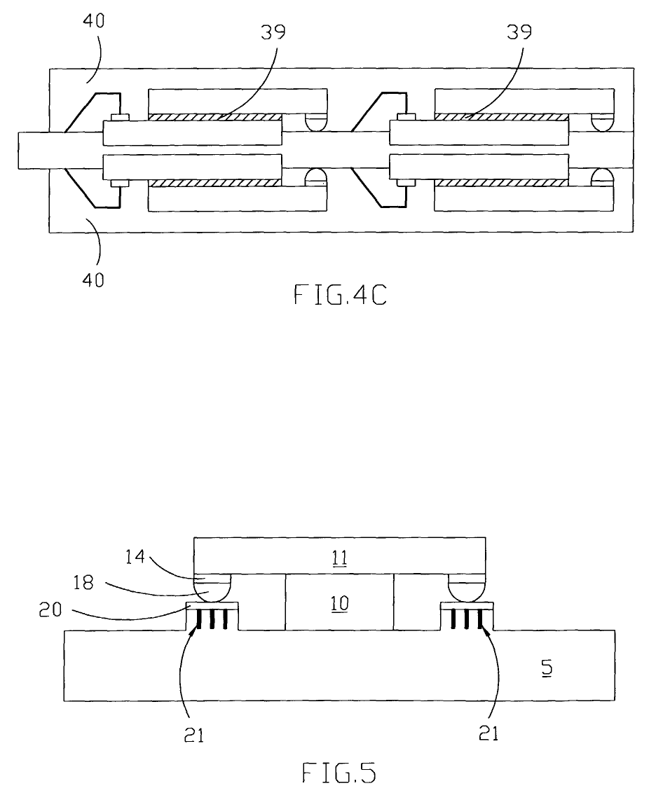

FIGS. 4A-4C are schematically cross-sectional views illustrating a variety of packaging devices in accordance with the present invention. FIG. 4A shows a stacked chip scale package(CSP) applying FIG. 1D in accordance with the present invention. A stack unit consists of the lower first die 10 and the upper second die 11, which is encapsulated on one side of the substrate 5 with molding compound 40 thereabout. The upper second die 11 is affixed to the lower first die 10 with the liquid non-conductive gel 39(or solid conductive film). There are multitudes of solder balls 41 under the other side of the substrate 5. It is note that the height of the molding compound 40 on the substrate 5 can be higher or equal to the height summation of the stacking dies, thus the dimension of the whole stack CSP is reduced. Furthermore, the arrangement for the stack units on the substrate 5 can be adjustable to reduce dimension in X-Y plane. FIG. 4B shows an applying packaging device BGA in accordance with the present invention. Multitudes of stack units are on one side of the substrate 5 and the other side of the substrate 5 includes the solder balls 41. FIG. 4C shows a high density memory card in accordance with the present invention. Multitudes of stacked chips are on both sides of the substrate 5.

FIG. 5 is a schematically cross-sectional diagram illustrating another interconnection between the upper die and the substrate in accordance with the present invention. In the embodiment, instead of the recesses of the substrate 5, there are lots of connective stud strips 20 parallel aligned corresponding to the locations of the bonding pads 14. There is also circuit layout 23 of the substrate 5 in the connective stud strips 20. With the liquid non-conductive gel or the solid film, the lower first die 10 is affixed to the surface of the substrate 5 between parallel connective stud strips 20. Next, similar to the embodiments mentioned above, the downward bonding pads 14 of the upper second die 11 are connected to the connective stud strips 20 of the substrate 5 by multitudes of predetermined stud bumpers 18, such as gold bumper or solder bumper.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A stacking multi-chip device, comprising:
a substrate having a recess thereon;
a first chip having a first back surface affixed in said recess and a first active surface, said first active surface comprising a plurality of first bonding pads which have a set of first conductors connected to said substrate; and
a second chip having a second back surface and a second active surface, said second active surface comprising a plurality of second bonding pads which have a set of second conductors connected to said substrate, wherein said second active surface is faced towards said first active surface and is offset stacked atop said first chip to expose both said first bonding pads and said second bonding pads.

2. The stacking multi-chip device of claim 1, wherein said second chip is shifted offset in one direction parallel to said first chip to expose a rectangular edge portion with said first bonding pads distributed thereon, and a rectangular edge portion with said second bonding pads distributed thereon.

3. The stacking multi-chip device of claim 1, wherein said second chip is shifted offset in one direction parallel to said first chip to expose a L-shaped edge portion on which the first bonding pads arc distributed, and a L-shaped edge portion on which the second bonding pads are distributed.

4. The stacking multi-chip device of claim 1, wherein said second chip is rotated in a plane substantially parallel to said first active surface of said first chip to expose two edge portions on which the first bonding pads are distributed and two edge portions on which the second bonding pads are distributed.

5. The stacking multi-chip device of claim 1, wherein said substrate is a ceramics substrate, a substrate with organic material, or a substrate with the mixture material thereof.

6. The stacking multi-chip device of claim 1, wherein said first conductors are metal bonding lines formed by wire bonding technology.

7. The stacking multi-chip device of claim 1, wherein said first conductors are a combination of solder bumps and wind-able conductive lines.

8. The stacking multi-chip device of claim 1, wherein said first conductors are a combination of solder bumps and lead-frames.

9. The stacking multi-chip device of claim 1, wherein said second conductors are stud bumps formed by wire bonding technology.

10. The stacking multi-chip device of claim 1, wherein said second conductors are stud bumps formed by wafer bumping technology.

11. The stacking multi-chip device of claim 1, further comprises a liquid non-conductive gel among said first bonding pad, said first conductors, and said substrate.

12. The stacking multi-chip device of claim 1, further comprises a liquid non-conductive gel filled among said second active surface, said second conductors, and said substrate.

13. A stacking multi-chip device, comprising:
a substrate having a plurality of first stud bump thereon;
a first chip having a first back surface affixed to said substrate and a first active surface, said first active surface comprising a plurality of first bonding pads which have a set of first conductors connected to said substrate; and
a second chip having a second back surface and a second active surface, said second active surface comprising a plurality of second bonding pads which have a set of second conductors connected to said first stud bumps, wherein location of each said second conductors is corresponding to location of each said first stud bumps, and said second active surface is faced towards said first active surface and is offset stacked atop said first chip to expose both said first bonding pads and said second bonding pads.

14. The stacking multi-chip device of claim 13, wherein said second chip is shifted offset in one direction parallel to said first chip to expose a first rectangular edge portion on which the first bonding pads are distributed, and a second rectangular edge portion on which the second bonding pads are distributed.

15. The stacking multi-chip device of claim 13, wherein said second chip is shifted offset in one direction parallel to said first chip to expose a first L-shaped edge portion on which the first bonding pads are distributed, and a second L-shaped edge portion on which the second bonding pads are distributed.

16. The stacking multi-chip device of claim 13, wherein said second chip is rotated in a plane substantially parallel to said first active surface of said first chip to expose two edge portions on which the first bonding pads are distributed, and two edge portions on which the second bonding pads are distributed.

17. The stacking multi-chip device of claim 13, wherein said substrate is a ceramics substrate, a substrate with organic material, or a substrate with the mixture material thereof.

18. The stacking multi-chip device of claim 13, wherein said first conductors are metal bonding lines formed by wire bonding technology.

19. The stacking multi-chip device of claim 13, wherein said first conductors are a combination of solder bumps and wind-able conductive lines.

20. The stacking multi-chip device of claim 13, wherein said first conductors are a combination of solder bumps and lead-frames.

21. The stacking multi-chip device of claim 13, wherein said second conductors are stud bumps formed by wire bonding technology.

22. The stacking multi-chip device of claim 13, wherein said second conductors are stud bumps formed by wafer bumping technology.

23. The stacking multi-chip device of claim 13, wherein said first conductors are predetermined stud bumpers.

24. The stacking multi-chip device of claim 13, wherein said first conductors are solder balls.

25. The stacking multi-chip device of claim 13, further comprises a liquid non-conductive gel among said first bonding pad, said first conductors, and said substrate.

26. The stacking multi-chip device of claim 13, further comprises a liquid non-conductive gel filled among said second active surface, said second conductors, and said substrate.

27. The stacking multi-chip device of claim 13, wherein said second conductors and said first stud bumps are connected by reflow technology.

28. The stacking multi-chip device of claim 13, wherein said second conductors and said first stud bumps are connected by an isotropic conductive gel.

29. A stacking multi-chip device, comprising:
a substrate having a plurality of conductive stud strips thereon, wherein said conductive stud strips comprise a plurality of pad and are electronic coupled with a circuit layout of said substrate;
a first chip having a first back surface affixed to said substrate and a first active surface, said first active surface comprising a plurality of first bonding pads which have a set of first conductors connected to said substrate; and
a second chip having a second back surface and a second active surface, said second active surface comprising a plurality of second bonding pads which have a set of second conductors connected to said pads, wherein locations of said second bonding pads are corresponding to locations of said pads, and said second active surface is faced towards said first active surface and is offset stacked atop said first chip to expose both said first bonding pads and said second bonding pads.

30. The stacking multi-chip device of claim 29, wherein said second chip is shifted offset in one direction parallel to said first chip to expose a first rectangular edge portion on which the first bonding pads are distributed and a second rectangular edge portion on which the second bonding pads are distributed.

31. The stacking multi-chip device of claim 29, wherein said second chip is shifted offset in one direction parallel to said first chip to expose a first L-shaped edge portion on which the first bonding pads are distributed and a second L-shaped edge portion on which the second bonding pads are distributed.

32. The stacking multi-chip device of claim 29, wherein said second chip is rotated in a plane substantially parallel to said first active surface of said first chip to expose two edge portions on which the first bonding pads are distributed and two edge portions on which the second bonding pads are distributed.

33. The stacking multi-chip device of claim 29, wherein said substrate is a ceramics substrate, a substrate with organic material, or a substrate with the mixture material thereof.

34. The stacking multi-chip device of claim 29, wherein said first conductors are metal bonding lines formed by wire bonding technology.

35. The stacking multi-chip device of claim 29, wherein said first conductors are a combination of solder bumps and wind-able conductive lines.

36. The stacking multi-chip device of claim 29, wherein said first conductors are a combination of solder bumps and lead-frames.

37. The stacking multi-chip device of claim 29, wherein said second conductors are stud bumps formed by wire bonding technology.

38. The stacking multi-chip device of claim 29, wherein said second conductors are stud bumps formed by wafer bumping technology.

39. The stacking multi-chip device of claim 29, further comprises a liquid non-conductive gel among said first bonding pad, said first conductors, and said substrate.

40. The stacking multi-chip device of claim 29, further comprises a liquid non-conductive gel filled among said second active surface, said second conductors, and said substrate.
